(19) United States
(12) Patent Application Publication
(10) Pub. No.: US 2024/0266426 A1
(43) Pub. Date: Aug. 8, 2024

(54) Semiconductor Structure for Improved Radio Frequency Thermal Management

(71) Applicant: Wolfspeed, Inc., Durham, NC (US)

(72) Inventors: Matthew R. King, Wake Forest, NC (US); Christer Hallin, Hillsborough, NC (US); Scott Sheppard, Chapel Hill, NC (US)

(21) Appl. No.: 18/164,249

(22) Filed: Feb. 3, 2023

(51) Int. Cl. H01L 29/778; H01L 29/20; H01L 29/201

(52) U.S. Cl. CPC H01L 29/7786; H01L 29/2003; H01L 29/201

(57) ABSTRACT

Semiconductor devices are provided. In one example, a semiconductor device may include a substrate. The semiconductor device may include an aluminum nitride layer on the substrate. The aluminum nitride layer having a thickness of about 200 nm or greater, such as about 400 nm or greater, such as in a range of 500 nm to 1000 nm. The semiconductor device may include a Group III-nitride semiconductor structure on the aluminum nitride layer.

### FIELD

The present disclosure relates generally to semiconductor devices.

### BACKGROUND

Power semiconductor devices are widely used to carry large currents, support high voltages and/or operate at high frequencies such as radio frequencies. A wide variety of power semiconductor devices are available for different applications including, for example, power switching devices and power amplifiers. Many power semiconductor devices are implemented using various types of field effect transistors (FETs) devices including MOSFETs (metal-oxide semiconductor field-effect transistors), DMOS (double-diffused metal-oxide semiconductor) transistors, HEMTs (high electron mobility transistors), MESFETs (metal-semiconductor field-effect transistors), LDMOS (laterally diffused metal-oxide semiconductor) transistors, etc.

Power semiconductor devices may be fabricated from wide band gap semiconductor materials (e.g., having a band-gap greater than 1.40 eV). For example, power HEMTs may be fabricated from gallium nitride (GaN) or other Group III nitride-based material systems that are formed, for instance, on a silicon carbide (SiC) substrate or other substrate. As used herein, the term “Group III nitride” refers to those semiconducting compounds formed between nitrogen and the elements in Group III of the periodic table, usually aluminum (Al), gallium (Ga), and/or indium (In). These compounds have empirical formulas in which one mole of nitrogen is combined with a total of one mole of the Group III elements. For high power, high temperature, and/or high frequency applications, devices formed in wide band gap semiconductor materials such as silicon carbide (e.g., 2.996 eV band gap for alpha silicon carbide at room temperature) and the Group III-nitrides (e.g., 3.36 eV band gap for gallium nitride at room temperature) may provide higher electric field breakdown strengths and higher electron saturation velocities as compared to gallium arsenide (GaAs) and silicon (Si) based devices.

### SUMMARY

Aspects and advantages of embodiments of the present disclosure will be set forth in part in the following description, or may be learned from the description, or may be learned through practice of the embodiments.

One example aspect of the present disclosure is directed to a semiconductor device. The semiconductor device may include a substrate. The semiconductor device may include an aluminum nitride layer on the substrate. The aluminum nitride layer having a thickness of about 200 nm or greater. The semiconductor device may include a Group III-nitride semiconductor structure on the aluminum nitride layer.

Another example aspect of the present disclosure is directed to a semiconductor device. The semiconductor device may include a substrate. The semiconductor device may include an aluminum nitride layer on the substrate, the aluminum nitride layer having a first thickness. The semiconductor device may include a gallium nitride layer on the aluminum nitride layer; wherein the gallium nitride layer has a second thickness. The first thickness is greater than the second thickness.

Another example aspect of the present disclosure is directed to a transistor device. The transistor device may include a substrate. The transistor device may include a Group III-nitride semiconductor structure on the substrate. The Group III-nitride semiconductor structure may include a first layer on the substrate and a second layer on the first layer. The first layer has a thickness that is greater than a thickness of the second layer. The first layer has a thermal conductivity that is greater than a thermal conductivity of the second layer.

Another example aspect of the present disclosure is directed to a method of forming a semiconductor device. The method may include forming an aluminum nitride layer on a substrate. The aluminum nitride layer may have a thickness of about 200 nm or greater. The method may include forming a Group III-nitride semiconductor structure on the aluminum nitride layer.

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which:

FIG. 1 depicts an example semiconductor structure for use in a semiconductor device according to example embodiments of the present disclosure;

FIG. 2 depicts an example transistor device according to example embodiments of the present disclosure;

FIG. 3 depicts an example semiconductor structure according to example embodiments of the present disclosure;

FIG. 4 depicts an example semiconductor structure according to example embodiments of the present disclosure;

FIG. 5 depicts metal-polar and nitrogen-polar (N-polar) Group-III nitride crystal structures;

FIG. 6 depicts an example transistor device according to example embodiments of the present disclosure;

FIG. 7 depicts an example transistor device according to example embodiments of the present disclosure;

FIG. 8 depicts a flow chart of an example method according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Semiconductor devices may be used in power electronics applications. For instance, transistor devices, such as high electron mobility transistor (HEMT) devices, may be used in power electronics applications. HEMTs fabricated in Group III-nitride based material systems may have the potential to generate large amounts of radio frequency (RF) power because of the combination of material characteristics that includes high breakdown fields, wide band gaps, large conduction band offset, and/or high saturated electron drift velocity. As such, Group III-nitride based HEMTs may be promising candidates for high frequency and/or high-power RF applications (as well as for low frequency high power switching applications) as discrete transistors or as coupled with other circuit elements, such as in monolithic microwave integrated circuit (MMIC) devices.

Field effect transistors such as HEMT devices may be classified into depletion mode and enhancement mode types, corresponding to whether the transistor is in an ON-state or an OFF-state at a gate-source voltage of zero. In enhancement mode devices, the devices are OFF at zero gate-source voltage, whereas in depletion mode devices, the device is ON at zero gate-source voltage. Often, high performance Group III nitride-based HEMT devices may be implemented as depletion mode (normally-on) devices, in that they are conductive at a gate-source bias of zero due to the polarization-induced charge at the interface of the barrier and channel layers of the device.

When an HEMT device is in an ON-state, a two-dimensional electron gas (2DEG) is formed at the heterojunction of two semiconductor materials with different band gap energies, where the smaller band gap material has a higher electron affinity. The 2DEG is an accumulation layer in the smaller band gap material and may include a very high sheet electron concentration. Additionally, electrons that originate in the wider-band gap semiconductor material transfer to the 2DEG layer, allowing high electron mobility due to reduced ionized impurity scattering. This combination of high carrier concentration and high carrier mobility may give the HEMT device a very large transconductance (which may refer to the relationship between output current and input voltage) and may provide a strong performance advantage over MOSFETs for high-frequency applications.

HEMT devices may include a Group III-nitride semiconductor structure having a thin aluminum nitride (AlN) nucleation layer (e.g., about 30 nm or less) formed on a substrate, such as silicon carbide (SiC) substrate. These Group III-nitride semiconductor structures may have a relatively high thermal resistance between, for instance, a gate contact of the HEMT device and the substrate. The relatively high thermal resistance may lead to increases in a junction temperature of the HEMT device during operation, particularly during high frequency and/or high-power operation associated with RF applications for HEMT devices. The high junction temperature reduces performance of the HEMT device in RF applications and reduces operational lifetime of the device.

Moreover, certain Group III-nitride semiconductor structures with thin AlN nucleation layers may include iron (Fe) doping in the Group III-nitride semiconductor structure (e.g., in a gallium nitride (GaN) layer of the Group III-nitride semiconductor structure) to compensate for impurities such that the Group III-nitride semiconductor structure is semi-insulating or is negatively charged. The iron (Fe) doping may allow an HEMT device to sustain high breakdown voltage and low leakage current. However, the iron doping may cause trapping effects, leading to performance degradation of the HEMT device in the form of current collapse and/or knee walkout. Current collapse is associated with a reduction in RF maximum drain current for the HEMT device relative to DC operation. Knee walkout is associated with a reduction in RF minimum drain voltage for the HEMT device under RF operation relative to DC operation.

Example aspects of the present disclosure provide a Group III-nitride semiconductor structure that leads to improved performance and reliability of semiconductor devices in RF applications. More specifically, the Group III-nitride semiconductor structure may include improved crystal quality and interfaces between layers in the semiconductor structure by significantly increasing a thickness of an AlN layer on a substrate while decreasing a thickness of other layers (e.g., a GaN layer) in the Group III-nitride semiconductor structure. The Group III-nitride semiconductor structure according to examples of the present disclosure may lead to lower junction temperatures of semiconductor devices in operation. The lower junction temperatures may lead to high output power and longer operational lifetime of the semiconductor devices. Moreover, the Group III-nitride semiconductor structure may provide improved trapping characteristics, leading to lower current collapse and knee walkout.

More specifically, examples of the present disclosure may include a semiconductor structure having a substrate, such as a SiC substrate. A Group III-nitride semiconductor structure may be on the substrate. The Group III-nitride semiconductor structure may have an AlN layer on the substrate and a buffer layer (e.g., a GaN layer) on the AlN layer. The AlN layer may have a thickness that is greater than a thickness of the buffer layer, such as at least 1.5 times greater than the thickness of the buffer layer. For instance, the AlN layer may have a thickness of about 200 nm or greater, such as about 300 nm or greater, such as about 500 nm or greater, such as in a range of about 500 nm to about 1000 nm.

The buffer layer may be a gallium nitride (GaN) layer. The buffer layer may not be doped or may be only unintentionally doped (e.g., does not include intentional iron (Fe) doping). The buffer layer may have a thickness in a range about 700 nm or less, such as about 400 nm or less, such as about 200 nm or less, such as in a range of about 100 nm to about 700 nm, such as in a range of about 100 nm to about 400 nm. Other Group III-nitride layers may be on the buffer layer, such as a barrier layer, one or more cap layers, etc.

Aspects of the present disclosure may provide technical effects and benefits. For instance, the thicker AlN layer may result in a much higher bulk crystal quality of the AlN layer and increased thermal conductivity relative to thin AlN layers (e.g., 30 nm or less). The use of a greater amount of AlN nitride relative to GaN for a bulk of the Group III-nitride semiconductor structure leads to increased thermal conductivity because AlN may have a higher intrinsic thermal conductivity relative to GaN. The thick AlN layer may also result in a lower thermal boundary resistance at an interface between the buffer layer (e.g., GaN layer) and the AlN layer. Moreover, the thick AlN layer may act as a thermal sink above an interface between the AlN layer and the substrate (e.g., SiC substrate) to provide good heat spreading via lateral heat conduction in the thick AlN layer.

Moreover, the thinner buffer layer (e.g., GaN layer) may lead to reduced thermal resistance from, for instance, a gate contact to the substrate of a transistor device incorporating the Group III-nitride semiconductor structure. Because the buffer layer is grown on a higher quality crystal structure of AlN, the buffer layer may have increased crystal quality and increased thermal conductivity. The thicker AlN layer may provide the possibility to control phonon density of states through strain engineering. More particularly, the thicker AlN layer may provide tensile strain in the AlN layer and compressive strain in the buffer layer to improve thermal conductivity of the Group III-nitride semiconductor structure.

Moreover, HEMT devices may include metal-polar (e.g., Ga-polar) or nitrogen-polar (e.g., N-polar) Group III-nitride semiconductor substrates. More specifically, Group III-nitride semiconductor structures may have a hexagonal wurtzite crystal structure that lacks inversion symmetry along a c-plane of the crystal structure. The lack of inversion symmetry may result in polarization effects. The polarization effects may lead to, for instance, a spontaneous polarization dipole in the Group III-nitride semiconductor structure. A direction associated with the spontaneous polarization dipole may determine whether the Group III-nitride semiconductor structure is metal-polar or N-polar. HEMT devices including N-polar Group III-nitride structures have recently been shown to deliver significant performance advantages, particularly at operating frequencies in the mm wave frequency ranges (e.g., 30 GHz or greater) relative to traditional metal-polar Group III-nitride semiconductor structures.

Aspects of the present disclosure may provide improvements to HEMT devices incorporating N-polar Group III-nitride semiconductor structures. For instance, in some examples, the thick AlN layer may serve as a back barrier layer for the HEMT device. A channel layer (e.g., GaN layer) may be on the AlN layer. The thick AlN back barrier layer may provide improved channel confinement of electrons in a 2DEG induced in the channel layer, leading to increased transconductance of the HEMT device.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the disclosure. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the disclosure. The thickness of layers and regions in the drawings may be exaggerated for clarity. Additionally, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the disclosure are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

Aspects of the present disclosure are discussed with reference to an HEMT transistor device for purposes of illustration and discussion. Those of ordinary skill in the art, using the disclosures provided herein, will appreciate that certain aspects of the present disclosure may be applicable to other semiconductor devices without deviating from the scope of the present disclosure, such as Schottky rectifiers.

In the drawings and specification, there have been disclosed typical embodiments and, although specific terms are employed, they are used in a generic and descriptive sense only and not for purposes of limitation of the scope set forth in the following claims.

As used herein, the term “Group III nitride” refers to those semiconducting compounds formed between nitrogen (N) and the elements in Group III of the periodic table, usually aluminum (Al), gallium (Ga), and/or indium (In). The term also refers to ternary and quaternary (or higher) compounds such as, for example, AlGaN, ScAIN and AlInGaN. As is well understood by those in this art, the Group III elements may combine with nitrogen to form binary (e.g., GaN), ternary (e.g., AlGaN, AlInN, ScAIN), and quaternary (e.g., AlInGaN) compounds. These compounds all have empirical formulas in which one mole of nitrogen is combined with a total of one mole of the Group III elements.

With reference now to the Figures, example embodiments of the present disclosure will now be set forth.

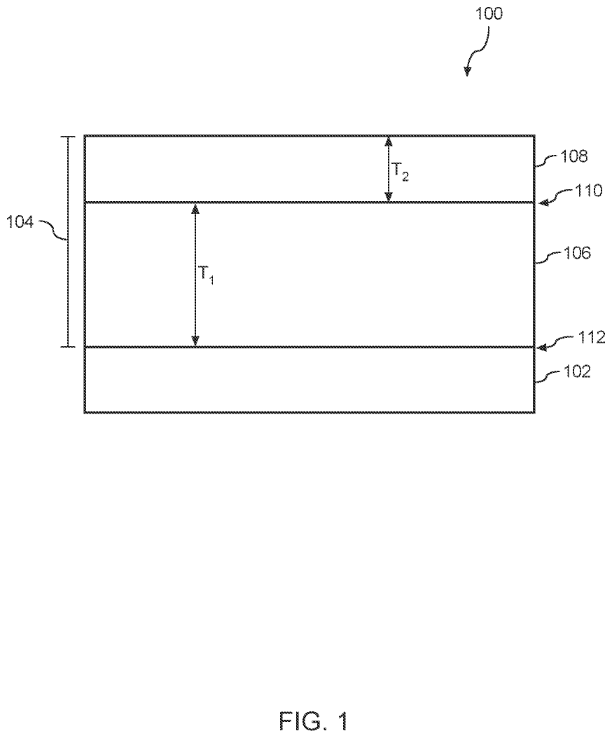

FIG. 1 depicts an example semiconductor structure 100 according to example embodiments of the present disclosure. FIG. 1 is intended to represent structures for identification and description and is not intended to represent the structures to physical scale. The semiconductor structure 100 includes a substrate 102 and a Group III-nitride semiconductor structure 104 on the substrate 102. The Group III-nitride semiconductor structure 104 may include an aluminum nitride (AlN) layer 106 and a buffer layer 108 (e.g., a gallium nitride (GaN) layer) on the AlN layer 106. The AlN layer 106 may have a thickness T₁ that is greater than a thickness T₂ of the buffer layer 108, such as at least 1.5 times greater than a thickness T₂ of the buffer layer 108. Additional layers may be included as part of the Group III-nitride semiconductor structure 104, such as one or more barrier layers, one or more channel layers, and/or one or more cap layers as will be described in detail below.

The substrate 102 may be a semiconductor material. For instance, the substrate 102 may be a silicon substrate, a silicon carbide (SiC) substrate, a sapphire substrate, or other suitable substrate. In some embodiments, the substrate 102 may be a semi-insulating SiC substrate that may be, for example, the 4H polytype of SiC or may be the 3C, 6H, and 15R polytypes of SiC. The substrate 102 may be a High Purity Semi-Insulating (HPSI) substrate, available from Wolfspeed, Inc. The term “semi-insulating” is used descriptively herein, rather than in an absolute sense.

In some embodiments, the SiC bulk crystal of the substrate 102 may have a resistivity equal to or higher than about 1×10⁵ ohm-cm at room temperature. Example SiC substrates that may be used in some embodiments are manufactured by, for example, Wolfspeed, Inc., and methods for producing such substrates are described, for example, in U.S. Pat. No. Re. 34,861, U.S. Pat. Nos. 4,946,547, 5,200,022, and 6,218,680, the disclosures of which are incorporated by reference herein. Although SiC may be used as a substrate material in some examples, other examples of the present disclosure may utilize any suitable substrate, such as sapphire (Al₂O₃), aluminum nitride (AlN), aluminum gallium nitride (AlGaN), gallium nitride (GaN), silicon (Si), GaAs, LGO, zinc oxide (ZnO), LAO, indium phosphide (InP), and the like. In some examples, the substrate 102 may have a thickness in a range of, for instance, about 50 μm to about 300 μm, such as in a range of about 75 μm to about 200 μm, such as about 100 μm.

The AlN layer 106 is formed directly on the substrate 102. The AlN layer 106 may be a AlᵥGa₁₋ᵥN, where the aluminum mole fraction v is 0.85≤v≤1. The AlN layer 106 may or may not include other Group III-nitrides such as InGaN, AlInGaN or the like. The AlN layer 106 may be undoped or only unintentionally doped. According to example aspects of the present disclosure, the AlN layer 106 may have a thickness T₁ in a range of about 200 nm or greater, such as about 300 nm or greater, such as about 500 nm or greater, such as in a range of about 500 nm to about 1000 nm. The AlN layer 106 may be formed using, for instance, metal-organic chemical vapor deposition (MOCVD), molecular beam epitaxy (MBE), or hydride vapor phase epitaxy (HVPE). Techniques for epitaxial growth of Group III-nitrides have been described in, for example, U.S. Pat. Nos. 5,210,051, 5,393,993, and 5,523,589, the disclosures of which are incorporated by reference herein. The AlN layer 106 may be metal-polar (e.g., Al-polar) or N-polar.

The AlN layer 106 may or may not be a homogenous film. In some examples, the AlN layer 106 may be faceted. In some examples, the AlN layer 106 has a graded concentration that changes as a function of depth or thickness of the AlN layer 106. For instance, the aluminum mole fraction of the AlN layer 106 may gradually increase or decrease as a function of distance from the substrate 102 (e.g., depth). In some examples, the AlN layer 106 may be a multi-layer structure. For instance, the AlN layer 106 may have a first AlN layer and a second AlN layer. The aluminum mole fraction of the first AlN layer may be greater than or less than an aluminum mole fraction of the second AlN layer. For instance, as one example, the first AlN layer may have an aluminum mole fraction of about 0.85. The second AlN layer may have an aluminum mole fraction of about 0.95.

The AlN layer 106 may have a high bulk crystal quality. The AlN layer 106 may have increased thermal conductivity (and reduced thermal resistivity) relative to thin AlN layers (e.g., 30 nm or less). For instance, the AlN layer 106 may have a thermal conductivity in a range of about 100 W/m·K to about 320 W/m·K at room temperature. The AlN layer 106 may provide a lower thermal boundary resistance at an interface 110 between the buffer layer 108 (e.g., GaN layer) and the AlN layer 106. Moreover, the thick AlN layer 106 may act as a thermal sink above an interface 112 between the AlN layer 106 and the substrate 102 (e.g., SiC substrate) to provide good heat spreading via lateral heat conduction in the thick AlN layer 106.

The buffer layer 108 (e.g., GaN layer) is formed directly on the AlN layer 106. The buffer layer 108 may be Al_{w}Ga_{1-w}N, where the aluminum mole fraction w is 0≤ w≤0.1. The buffer layer 108 may or may not include other Group III-nitrides such as InGaN, AlInGaN or the like. The buffer layer 108 may be undoped or may be only unintentionally doped. According to example aspects of the present disclosure, the buffer layer 108 may have a thickness T₂ in a range about 700 nm or less, such as about 400 nm or less, such as about 200 nm or less, such as in a range of 100 nm to 700 nm, such as in a range of about 100 nm to about 400 nm. The buffer layer 108 may have a thermal conductivity in a range of about 100 W/m·K to about 300 W/m·K at room temperature. The buffer layer 108 may be formed using, for instance, metal-organic chemical vapor deposition (MOCVD), molecular beam epitaxy (MBE), or hydride vapor phase epitaxy (HVPE). The buffer layer 108 may be metal-polar (e.g., Ga-polar) or N-polar.

The thick AlN layer 106 may induce tensile strain in the AlN layer 106. The thick AlN layer 106 may induce compressive strain in the buffer layer 108. These strain states may lead to improved thermal conductivity of the Group III-nitride semiconductor structure 104 as well as desirable phonon density of states.

The semiconductor structure 100 may be used in a variety of semiconductor devices, such as HEMT devices. In some examples, the buffer layer 108 may be a channel layer of an HEMT device as will be described in detail below.

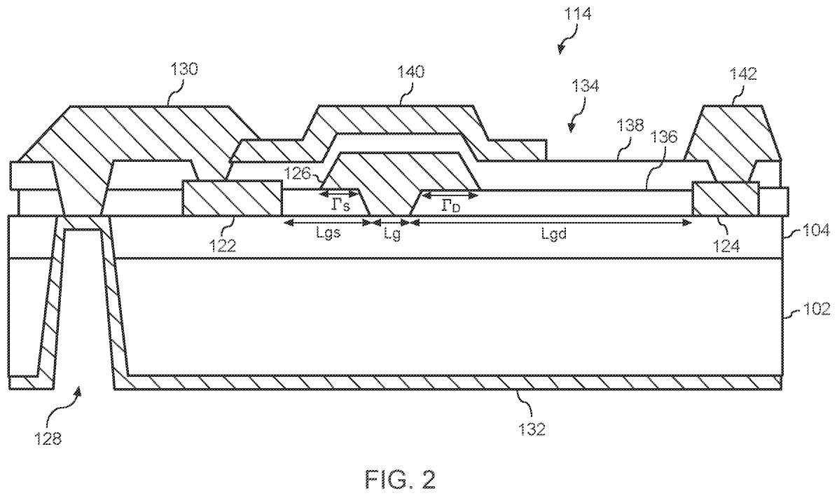

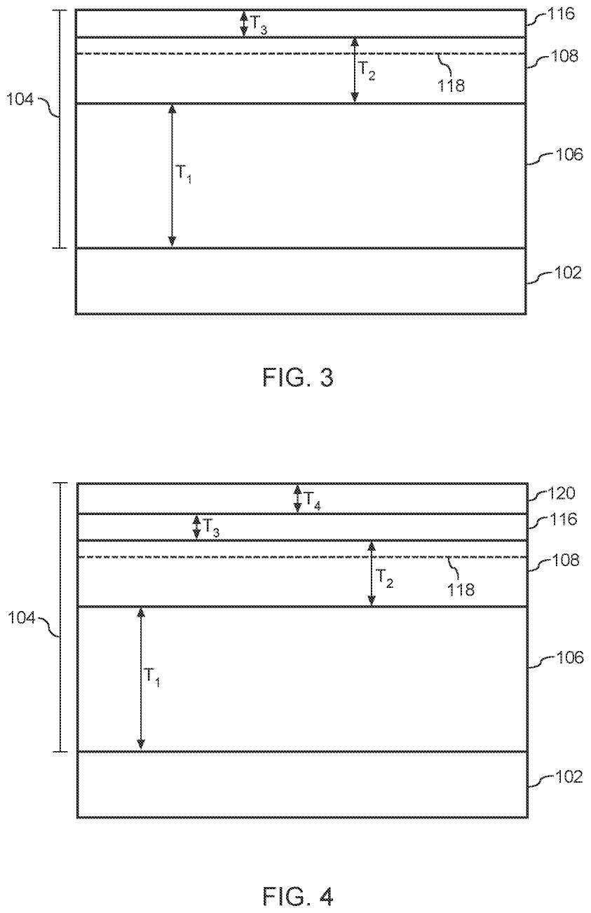

For instance, FIG. 2 depicts a cross-sectional view of an example HEMT device 114 according to example embodiments of the present disclosure. FIG. 1 is intended to represent structures for identification and description and is not intended to represent the structures to physical scale. The HEMT device 114 may include a Group III-nitride semiconductor structure 104, such as the Group III-nitride semiconductor structure of FIG. 1 or the Group III-nitride semiconductor structure 104 of FIG. 3 or FIG. 4.

The Group III-nitride semiconductor structure 104 may be on a substrate 102, such as the substrate 102 of FIG. 1. The substrate 102 may be a SiC wafer, and the HEMT device 114 may be formed, at least in part, via wafer-level processing, and the wafer may then be diced to provide a plurality of individual HEMT devices 114 that may include one or more transistor cells. In some embodiments, the substrate 102 of the HEMT device 114 may be a thinned substrate 102. In some embodiments, the thickness of the substrate 102 may be about 100 μm or less, such as about 75 μm or less, such as about 50 μm or less.

FIG. 3 depicts a Group III-nitride semiconductor structure 104 on a substrate 102 that may be used in the HEMT device 114 according to example embodiments of the present disclosure. As shown the Group III-nitride semiconductor structure 104 includes a thick AlN layer 106. The AlN layer 106 is formed on the substrate 102. The AlN layer 106 may be AlᵥGa₁₋ᵥN, where 0.85≤ v≤1. The AlN layer 106 may or may not include other Group III-nitrides such as InGaN, AlInGaN or the like. The AlN layer 106 may be undoped or only unintentionally doped. According to example aspects of the present disclosure, the AlN layer 106 may have a thickness T₁ in a range of about 200 nm or greater, such as about 300 nm or greater, such as about 500 nm or greater, such as in a range of about 500 nm to about 1000 nm. The AlN layer 106 may be formed using, for instance, metal-organic chemical vapor deposition (MOCVD), molecular beam epitaxy (MBE), or hydride vapor phase epitaxy (HVPE). The AlN layer 106 of FIG. 3 may be metal-polar (e.g., Al-polar).

The Group III-nitride semiconductor structure 104 may include a buffer layer 108. The buffer layer 108 may be a channel layer for the HEMT device 114. The buffer layer 108 may be Al_{w}Ga_{1-w}N, where w is 0≤ w≤0.1. The buffer layer 108 may or may not include other Group III-nitrides such as InGaN, AlInGaN or the like. The buffer layer 108 may be undoped or may be only unintentionally doped. According to example aspects of the present disclosure, the buffer layer 108 may have a thickness T₂ in a range about 700 nm or less, such as about 400 nm or less, such as about 200 nm or less, such as in a range of 100 nm to 700 nm, such as in a range of about 100 nm to about 400 nm. The buffer layer 108 may be formed using, for instance, metal-organic chemical vapor deposition (MOCVD), molecular beam epitaxy (MBE), or hydride vapor phase epitaxy (HVPE). The buffer layer 108 may be metal-polar (e.g., Ga-polar).

The semiconductor structure 104 may include a barrier layer 116 on an upper surface of the buffer layer 108. The barrier layer 116 may have a bandgap that is different than the bandgap of the buffer layer 108. The energy of the conduction band edge of the barrier layer 116 may be greater than the energy of the conduction band edge of the buffer layer 108 at the interface between the buffer layer 108 and the barrier layer 116. The barrier layer 116 may be a Group III-nitride, such as AlₓGa₁₋ₓN, where x is the aluminum mole fraction in the barrier layer 116. In some embodiments, the aluminum mole fraction x is such that x is in a range of about 0.15 to about 0.30, such as about 0.20 to about 0.25, such as about 0.22 (e.g., the aluminum mole fraction is in a range of 15% to 30%, such as in a range of about 20% to about 25%, such as about 22%), indicating that the barrier layer is an AlGaN layer. The barrier layer 116 may include other Group III elements (e.g., In) without deviating from the scope of the present disclosure. The barrier layer 116, in some examples, may be a multilayer structure. The multilayer structure may include multiple Group III nitride-based layers with differing aluminum mole fractions. The barrier layer 116 may have a thickness T₃ in a range of about 10 Angstroms to about 300 Angstroms, such as about 120 Angstroms to about 170 Angstroms, such as about 150 Angstroms. The barrier layer 116 may be deposited, for example, by metal-organic chemical vapor deposition (MOCVD), molecular beam epitaxy (MBE), or hydride vapor phase epitaxy (HVPE).

A 2DEG 118 may be induced in the buffer layer 108 at an interface between the buffer layer 108 and the barrier layer 116. The 2DEG 118 is highly conductive and allows conduction between the source and drain regions of the HEMT device 114.

FIG. 4 depicts an example Group III-nitride semiconductor structure 104 that is similar to the Group III-nitride semiconductor structure 104 of FIG. 4. The Group III-nitride semiconductor structure of FIG. 4 additionally includes a cap layer 120. The cap layer 120 may be a Group III-nitride, such as a GaN layer (doped or undoped). The cap layer 120 may be other materials, such as silicon and/or germanium. The cap layer 120 may have a thickness T₄. The thickness T₄ may be in a range of about 20 Angstroms to about 50 Angstroms.

Referring back to FIG. 2, the HEMT device 114 may include additional layers and/or structures without deviating from the scope of the present disclosure. HEMT structures including substrates, channel layers, barrier layers, and other layers are discussed by way of example in U.S. Pat. Nos. 5,192,987, 5,296,395, 6,316,793, 6,548,333, 7,544,963, 7,548, 112, 7,592,211, 7,615,774, 7,709,269, 7,709,859 and 10,971,612, the disclosures of which are incorporated by reference herein. Additionally, strain balancing transition layer(s) may also and/or alternatively be provided as described, for example, in U.S. Pat. No. 7,030,428, the disclosure of which is incorporated by reference herein.

Referring to FIG. 2, the HEMT device 114 may include a source contact 122 on the semiconductor structure 104 or otherwise contacting the semiconductor structure 104. The HEMT device 114 may include a drain contact 124 on the semiconductor structure 104 or otherwise contacting the semiconductor structure 104. The source contact 122 and the drain contact 124 may be laterally spaced apart from each other. In some embodiments, the source contact 122 and the drain contact 124 may include a metal that may form an ohmic contact to a Group III nitride-based semiconductor material. Suitable metals may include refractory metals, such as titanium (Ti), tungsten (W), titanium tungsten (TiW), silicon (Si), titanium tungsten nitride (TiWN), tungsten silicide (WSi), rhenium (Re), niobium (Nb), nickel (Ni), gold (Au), aluminum (Al), tantalum (Ta), molybdenum (Mo), NiSiₓ, titanium silicide (TiSi), titanium nitride (TiN), tungsten silicon nitride (WsiN), platinum (Pt) and the like. In some embodiments, the source contact 122 may be an ohmic source contact 122. The drain contact 124 may be an ohmic drain contact 124. Thus, the source contact 122 and/or the drain contact 124 may include an ohmic contact portion in direct contact with the barrier layer 116. In some embodiments, the source contact 122 and/or the drain contact 124 may include a plurality of layers to form an ohmic contact that may be provided as described, for example, in U.S. Pat. Nos. 8,563,372 and 9,214,352, the disclosures of which are incorporated by reference herein.

The HEMT device 114 may include a gate contact 126 on the semiconductor structure 104 or otherwise contacting the semiconductor structure 104 (e.g., at least partially recessed into the semiconductor structure 104). The gate contact 126 may have a gate length LG. The gate length LG may be the length of the gate contact 126 along the portion of the gate contact 126 that is on the semiconductor structure 104 (e.g., the length of the lowermost portion of the gate contact 126 in contact with the semiconductor structure 104). In some embodiments, the gate length LG may be about 200 nm or less, such as about 150 nm or less, such as in a range of about 60 nm to about 200 nm, such as in a range of about 90 nm to about 150 nm. A distance Lgd between the gate contact 126 and the drain contact 124 may be, for instance, in a range of 1.8 μm to about 2.2 μm, such as about 1.98 μm. A distance Lgs between the gate contact 116 and the source contact 122 may be, for instance, in a range of about 0.4 μm to about 0.8 μm, such as about 0.6 μm.

The material of the gate contact 126 may be chosen based on the composition of the barrier layer 116, and may, in some embodiments, be a Schottky contact. Materials capable of making a Schottky contact to a Group III nitride-based semiconductor material may be used, such as, for example, nickel (Ni), platinum (Pt), nickel silicide (NiSiₓ), copper (Cu), palladium (Pd), chromium (Cr), tungsten (W) and/or tungsten silicon nitride (WSiN).

In some embodiments, the gate contact 126 may be a T-shaped gate and/or a gamma gate, the formation of which is discussed by way of example in U.S. Pat. Nos. 8,049,252, 7,045,404, and 8,120,064, the disclosures of which are incorporated by reference herein. The gate contact 126 may have an overhang toward the drain contact 124. The length Γ_{D} of the overhang toward the drain contact 124 may be in a range of about 0.15 μm to about 0.25 μm, such as about 0.2 μm. The gate contact 126 may have an overhang toward the source contact 122. The length Γ_{S} of the overhang toward the source contact 122 may be in a range of about 0.15 μm to about 0.25 μm, such as about 0.2 μm.

The source contact 122 may be coupled to a reference signal such as, for example, a ground voltage or other reference signal. The coupling to the reference signal may be provided by a via 128 that extends from a lower surface of the substrate 102, through the substrate 102 and semiconductor structure 104 to the upper surface of the semiconductor structure 104. The via 128 may be coupled to a metal contact 130. The metal contact 130 may include metal or other highly conductive material, including, for example, copper, cobalt, gold, and/or a composite metal. The metal contact 130 may conductively couple the via 128 to the source contact 122. A back metal layer 132 may be on the lower surface of the substrate 102 and on side walls of the via 128. The back metal layer 132 may be conductively coupled to the metal contact 130. Thus, the back metal layer 132, and a signal coupled thereto, may be electrically connected to the source contact 122 through the metal contact 130.

In some embodiments, the via 128 may have an oval or circular cross-section when viewed in a plan view. However, the present disclosure is not limited thereto. In some embodiments, a cross-section of the via 128 may be a polygon or other shape, as will be understood by one of ordinary skill in the art using the disclosures provided herein. In some embodiments, dimensions of the via 128 (e.g., a length and/or a width) may be such that a largest cross-sectional area of the via 128 is about 1000 μm² or less. The cross-sectional area may be taken in a direction that is parallel to the lower surface of the substrate 102 (e.g., the X-Y plane of FIG. 1). In some embodiments, the largest cross-sectional area of the via 128 may be that portion of the via 128 that is adjacent the lower surface of the substrate 102 (e.g., the opening of the via 128). For example, in some embodiments, a greatest width may be about 16 μm and a greatest length may be about 40 μm, though the present disclosure is not limited thereto. In some embodiments, sidewalls of the via 128 may be inclined and/or slanted with respect to the lower surface of the substrate 102. In some embodiments, the sidewalls of the via 128 may be approximately perpendicular to the lower surface of the substrate 102.

In some examples, the drain contact 124 may be formed on, in and/or through the semiconductor structure 104, and there may be ion implantation into the materials around the drain contact 124 to reduce resistivity and provide improved ohmic contact to the semiconductor material. In yet other embodiments, there is no source via 128, and the source contact 122 is formed on, in and/or through the semiconductor structure 104, and there may be ion implantation in the materials around the source contact 122 to reduce resistivity and provide improved ohmic contact to the semiconductor material. Where there is no source via 128, the electrical connections to the source contact 122 may be made on the same side as the gate contact 126 and the drain contact 124. In some examples, the connections to the source contact 122, drain contact 124, and/or gate contact 126 may be made from the top and/or the bottom to provide for flip chip configuration of the HEMT device 114. In some examples, thermal paths may be provided from the top and/or bottom to provide for flip chip configuration of the HEMT device 114.

The HEMT device 114 may include a dielectric structure 134 on the semiconductor structure 104. The dielectric structure 134 may include a first dielectric layer 136 and a second dielectric layer 138. The first dielectric layer 136 may directly contact the upper surface of the semiconductor structure 104. At least a portion of the first dielectric layer 136 may be between the semiconductor structure 104 and at least a portion of the gate contact 126. For instance, at least a portion of the first dielectric layer 136 may be between the semiconductor structure 104 and the overhang of the gate contact 126. The first dielectric layer 136 may be a SiN layer. Other suitable dielectric materials may be used without deviating from the scope of the present disclosure. For instance, the first dielectric layer 136 may be SiO₂, Si, Ge, MgOx, MgNx, ZnO, SiNx, SiOx, alloys or layer sequences thereof, or epitaxial materials.

The dielectric structure 134 may include a second dielectric layer 138 on the first dielectric layer 136. The second dielectric layer 138 may be the same dielectric material or a different dielectric material relative to the first dielectric layer 136. For instance, the second dielectric layer 138 may be a SiN layer. Other suitable dielectric materials may be used without deviating from the scope of the present disclosure. For instance, the second dielectric layer 138 may be SiO₂, Si, Ge, MgOx, MgNx, ZnO, SiNx, SiOx, alloys or layer sequences thereof, or epitaxial materials.

One or more field plates 140 may be on the dielectric structure 134 as illustrated in FIG. 2. At least a portion of a field plate 140 may be overlapping the gate contact 126. At least a portion of the field plate 140 may be on a portion of the second dielectric layer 138. In some embodiments, the field plate 140 may be conductively coupled to the gate contact 126. The field plate 140 may reduce the peak electric field in the HEMT device 114, which may result in increased breakdown voltage and reduced charge trapping. The reduction of the electric field may also yield other benefits such as reduced leakage currents and enhanced reliability. Field plates and techniques for forming field plates are discussed, by way of example, in U.S. Pat. No. 8,120,064, the disclosure of which is incorporated by reference herein.

Metal contacts 130 and 142 may be at least partially in the dielectric structure 134 as illustrated in FIG. 2. The metal contacts 130 and 142 may provide interconnection between the source contact 122, drain contact 124, gate contact 126, and other parts of the HEMT device 114. Metal contact 130 may be conductively coupled to the source contact 122. Metal contact 142 may be conductively coupled to the drain contact 124. The metal contacts 130 and 142 may include metal or other highly conductive material, including, for example, copper, cobalt, gold, and/or a composite metal.

A HEMT transistor cell may be formed by the active region between the source contact 122 and the drain contact 124 under the control of the gate contact 126 between the source contact 122 and the drain contact 124. FIG. 2 depicts a cross-sectional view of one unit or cell of an HEMT device 114 for purposes of illustration. The HEMT device unit or cell may be formed adjacent to additional HEMT device cells and may share, for instance, a source contact 122 with adjacent HEMT device cells. The HEMT device 114 may be formed, at least in part, via wafer-level processing, and the wafer may then be diced to provide a plurality of individual HEMT devices 114.

The HEMT device 114 of FIG. 2 may be based on a metal-polar Group III-nitride semiconductor structure. In some examples, the semiconductor devices according to example embodiments of the present disclosure may include Group III-nitride semiconductor structures that are N-polar. More specifically, Group III-nitride semiconductor structures may have a hexagonal wurtzite crystal structure that lacks inversion symmetry along a c-plane of the crystal structure. The lack of inversion symmetry may result in polarization effects. The polarization effects may lead to, for instance, a spontaneous polarization dipole in the Group III-nitride semiconductor structure. A direction associated with the spontaneous polarization dipole may determine whether the Group III-nitride semiconductor structure is metal-polar or N-polar.

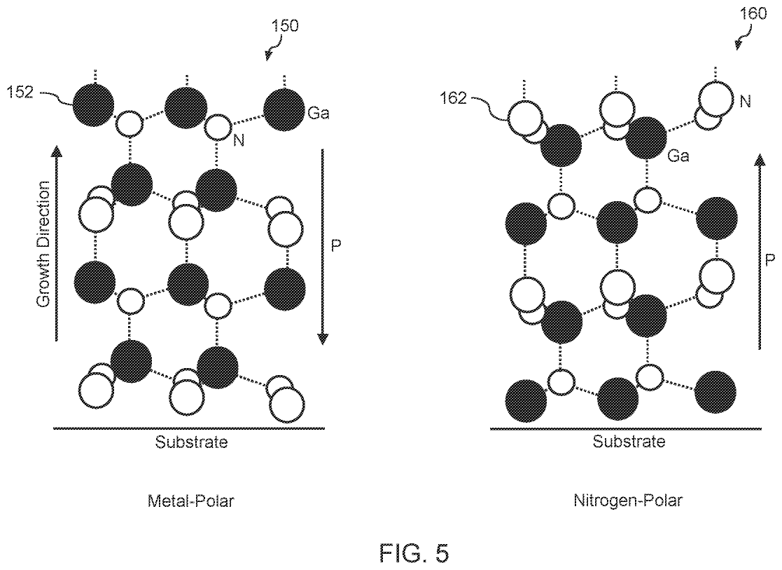

For instance, FIG. 5 depicts an example metal-polar Group III nitride semiconductor structure 150 (e.g., Ga-polar GaN) and an example N-polar Group III-nitride semiconductor structure 160 (e.g., N-polar GaN). As shown, the metal-polar Group III-nitride semiconductor structure 150 and the N-polar Group III-nitride semiconductor structure 160 each have a hexagonal wurtzite crystal structure. In a wurtzite crystal structure, the metal (e.g., gallium) and the nitrogen are arranged in separate distinct layers. The metal-polar (e.g., Ga-polar) Group III-nitride semiconductor structure 150 has a metal face 152 (e.g., gallium face) in the growth direction of the semiconductor structure 150 relative to a substrate. The direction of the spontaneous polarization dipole P may be opposite the growth direction in the metal-polar Group III-nitride semiconductor structure 150. The N-polar semiconductor structure 160 has a nitrogen face 162 in the growth direction of the semiconductor structure 160 relative to a substrate. The direction of the spontaneous polarization dipole P may be the same as the growth direction in the N-polar Group III-nitride semiconductor structure 160.

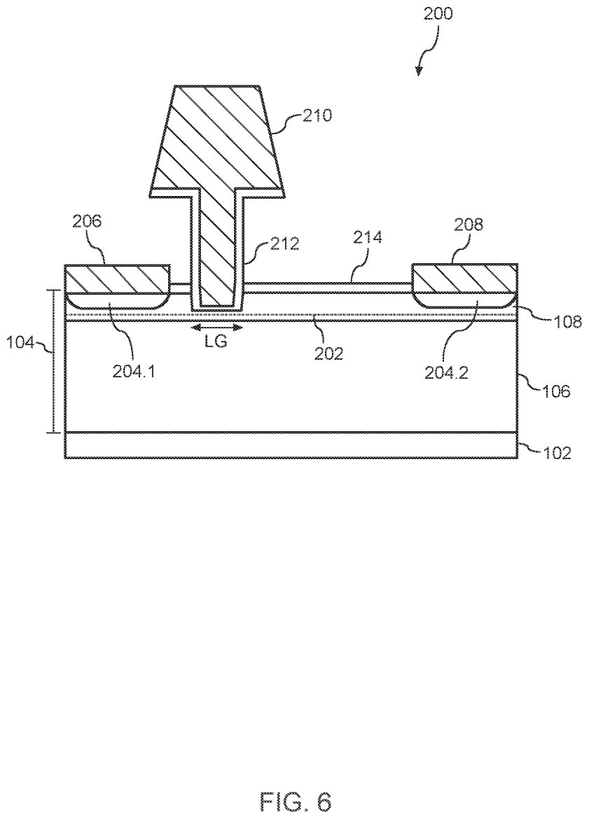

FIG. 6 depicts an example HEMT device 200 incorporating an N-polar Group III-nitride semiconductor structure 104 on a substrate 102 (e.g., an SiC substrate) according to example embodiments of the present disclosure. FIG. 6 is intended to represent structures for identification and description and is not intended to represent the structures to physical scale. The HEMT device 200 may include a semiconductor structure 104 (e.g., as discussed with reference FIG. 1) that includes an N-polar AlN layer 106, an N-polar buffer layer 108 on the N-polar AlN layer, and a substrate 102. The substrate 102 may have the same properties as the substrate 102 of FIG. 1.

The N-polar AlN layer 106 of FIG. 6 may have the same properties as the AlN layer 106 described with reference to FIG. 1, except that the AlN layer 106 of FIG. 6 is N-polar. The N-polar buffer layer 108 of FIG. 6 may have the same properties as the buffer layer 108 discussed with reference to FIG. 1, except that the buffer layer 108 of FIG. 6 is N-polar.

The N-polar AlN layer 106 may have a thickness that is greater than a thickness of the N-polar buffer layer 108, such as at least 1.5 times greater than the thickness of the N-polar buffer layer 108. For instance, the N-polar AlN layer 106 may have a thickness of about 200 nm or greater, such as about 300 nm or greater, such as about 500 nm or greater, such as in a range of about 500 nm to about 1000 nm. The N-polar buffer layer 108 may have a thickness in a range about 700 nm or less, such as about 400 nm or less, such as about 200 nm or less, such as in a range of 100 nm to 700 nm, such as in a range of about 100 nm to about 400 nm.

The N-polar AlN layer 106 may act as a back barrier layer for the HEMT device 200. The N-polar buffer layer 108 may act as a channel layer for the HEMT device 200. A 2DEG 202 may be induced in the buffer layer 108 at the interface between the buffer layer 108 and the AlN layer 106. The 2DEG 202 is highly conductive and allows conduction between the source and drain regions of the HEMT device 200. The 2DEG 202 may be controlled under operation of a gate, such that the HEMT device 200 acts as a controllable transistor device.

The semiconductor structure 104 may include implanted regions 204.1 and 204.2. The implanted regions 204.1 and 204.2 may include a distribution of implanted dopants (e.g., ions) of a first conductivity type such that the implanted regions 204.1 and 204.2 are n-type regions. The implanted regions 204.1 and 204.2 may extend through the semiconductor structure 104 into the buffer layer 108.

The implanted regions 204.1 and 204.2 may include a distribution of implanted dopants extending into the buffer layer 108. The implanted dopants may be of a first conductivity type such that the implanted regions 204.1 and 204.2 are each an n-type region. The implanted dopants may be, for instance, silicon, germanium, sulfur, and/or oxygen ions.

The implanted regions 204.1 and 204.2 may each have a peak dopant concentration of 1×10¹⁸ ions/cm³ or greater. For example, in some embodiments, the dose and energy of the implants may be selected to provide a peak dopant concentration of about 5×10²⁰ ions/cm³ in the implanted regions 204.1 and 204.2. The distribution of implanted dopants in the implanted regions 204.1 and 204.2 may have its peak dopant concentration at a depth in the implanted regions 204.1 and 204.2 in the buffer layer 108 of the semiconductor structure 104.

The HEMT device 200 includes electrodes on the implanted regions 204.1 and 204.2. More particularly, the HEMT device 200 may include a source contact 206 on the implanted region 204.1. The HEMT device 200 may include a drain contact 208 on the implanted region 204.2. The electrodes may form an ohmic contact with the respective implanted regions 204.1 and 204.2. The implanted dopants within implanted region 204.1 may provide a low resistive path between the ohmic source contact 206 and the buffer layer 108. For instance, the implanted region 204.1 may have a dopant concentration such that the implanted region 204.1 has a resistivity in a range of about 0.2 Ohms-mm or less. The implanted dopants within implanted region 204.2 may provide a low resistive path between the ohmic drain contact 208 and the buffer layer 108. For instance, the implanted region 204.2 may have a dopant concentration such that the implanted region 204.2 has a resistivity in a range of about 0.2 Ohms-mm or less.

The source contact 206 and the drain contact 208 may be laterally spaced apart from each other. In some embodiments, the source contact 206 and the drain contact 208 may include a metal that may form an ohmic contact to a Group III-nitride based semiconductor material. Suitable metals may include refractory metals, such as titanium (Ti), tungsten (W), titanium tungsten (TiW), silicon (Si), titanium tungsten nitride (TiWN), tungsten silicide (WSi), rhenium (Re), niobium (Nb), Ni, gold (Au), aluminum (Al), tantalum (Ta), molybdenum (Mo), NiSiₓ, titanium silicide (TiSi), titanium nitride (TiN), tungsten silicon nitride (WSiN), platinum (Pt) and the like. In some embodiments, the source contact 206 may be an ohmic contact. The drain contact 208 may be an ohmic contact. In some embodiments, the source contact 206 and/or the drain contact 208 may include a plurality of layers to form an ohmic contact that may be provided as described, for example, in U.S. Pat. Nos. 8,563,372 and 9,214,352, the disclosures of which are incorporated by reference herein.

The HEMT device 200 may include a gate contact 210. The gate contact 210 may extend at least partially through a trench (e.g., an ALE defined trench) in the buffer layer 108. In some examples, the gate contact 210 may have a gate length LG in a range of about 50 nm to about 150 nm. The gate length is the length of the gate contact 210 along the surface proximate the buffer layer 108.

A passivation layer 212 may be located between the gate contact 210 and the buffer layer 108. The passivation layer 212 may be SiN. Other suitable dielectric layers may be used as the passivation layer 212, such as SiO₂, MgOx, MgNx, ZnO, SiNx, SiOx or other dielectric layers. The passivation layer 212 may be formed, for instance, using MOCVD process(s), atomic layer deposition (ALD) process(s), and/or sputter deposition processes. The passivation layer 212 may serve as a gate dielectric. In some examples, the passivation layer 212 may have a thickness, for instance, of about 5 Angstroms to about 100 Angstroms, such as about 10 Angstroms to about 50 Angstroms.

The gate contact 210 may be a T-shaped gate or a gamma gate, the formation of which is discussed by way of example in U.S. Pat. Nos. 8,049,252, 7,045,404, and 8,120,064, the disclosures of which are incorporated by reference herein. Materials capable of making a contact to a Group III-nitride based semiconductor material may be used, such as, for example, nickel (Ni), platinum (Pt), nickel silicide (NiSiₓ), copper (Cu), palladium (Pd), chromium (Cr), tungsten (W) and/or tungsten silicon nitride (WSiN).

The HEMT device 200 may include additional passivation layer(s) 214 on the semiconductor structure 104, the gate contact 210, and/or other structures of the HEMT device 200. The additional passivation layer(s) 214 may be, for instance, dielectric materials, such as SiO₂, MgOx, MgNx, ZnO, SiNx, SiOx, alloys or layer sequences thereof. The additional passivation layer(s) 214 may be formed using MOCVD process(s), ALD process(s), sputter deposition process(s), or other suitable process(s). One or more insulating layers (not shown) may be on the HEMT device 200. For instance, the HEMT device 200 may be encapsulated in an insulating material without deviating from the scope of the present disclosure.

A transistor may be formed by the active region between the source contact 206 and the drain contact 208 under the control of a gate contact 210 between the source contact 206 and the drain contact 208. FIG. 6 depicts a cross-sectional view of one unit of an HEMT device 200 for purposes of illustration. The HEMT device 200 may be formed adjacent to additional HEMT device units and may share, for instance, a source contact 206 with adjacent HEMT device units.

In some examples, the HEMT device 200 may be operable at frequencies of up to about 150 GHz. For instance, the HEMT device 200 may be operable at a frequency in a range of about 10 GHz to about 150 GHz, such as in a range of about 30 GHz to about 150 GHz, such as in a range of about 50 GHz to about 150 GHz. In some examples, the HEMT device 200 may have a power density of up to 10 W/mm or greater in these frequency ranges, such as a power density in a range of 2.5 W/mm to about 12 W/mm.

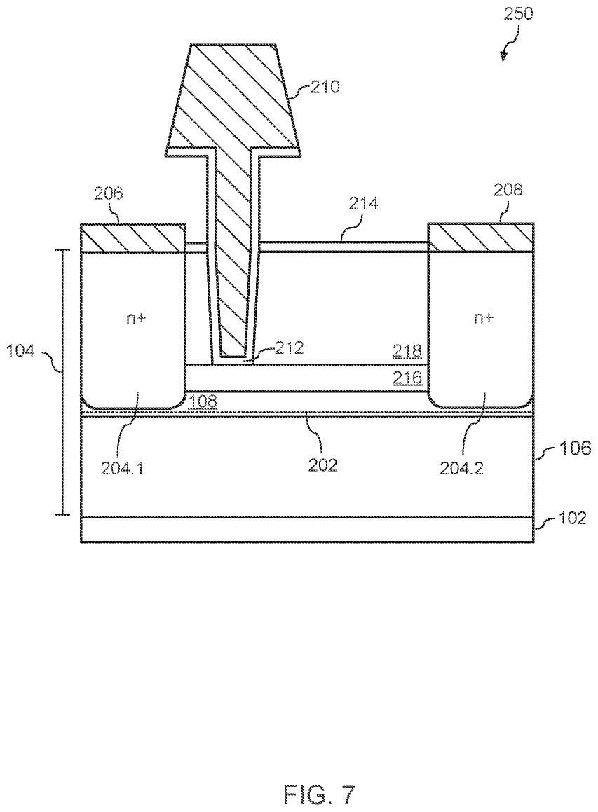

FIG. 7 depicts an example HEMT device 250 incorporating an N-polar Group III-nitride semiconductor structure 104 according to example embodiments of the present disclosure. FIG. 7 is intended to represent structures for identification and description and is not intended to represent the structures to physical scale. The HEMT device 250 is similar to the HEMT device 200 of FIG. 6. However, the N-polar Group III-nitride semiconductor structure 104 of the HEMT device 250 of FIG. 7 additionally includes a first cap layer 216 and a second cap layer 218.

The first cap layer 216 may be on the buffer layer 108. The first cap layer 216 may be an N-polar Group III-nitride, such as Al_{y}Ga_{1-y}N where 0.1≤y<0.4, indicating that the first cap layer 216 is an AlGaN layer. In some embodiments, the aluminum mole fraction y is in a range of about 0.2 to about 0.3. The first cap layer 216 may or may not include other Group III-nitrides such as InGaN, AlInGaN or the like. The first cap layer 216 may have a band gap that is different than the band gap of the buffer layer 108. The first cap layer 216 may have a thickness in a range of about 15 Angstroms to about 50 Angstroms, such as about 26 Angstroms.

A second cap layer 218 may be on the first cap layer 216. The second cap layer 218 may be an N-polar Group III-nitride, such as Al_{z}Ga_{1-z}N, where 0≤z<0.1. In some embodiments, the aluminum mole fraction z is approximately 0 (e.g., 0.1 or less), indicating that the second cap layer is a GaN layer. The second cap layer 218 may or may not include other Group III-nitrides such as InGaN, AlInGaN or the like. The second cap layer 218 buries the buffer layer 108 deep below the surface of semiconductor structure 104 such that the buffer layer 108 is a buried layer at a depth of about 275 Angstroms or greater from the surface of the semiconductor structure 104, such as about 500 Angstroms or greater from the surface of the semiconductor structure 104, such as in a range of about 275 Angstroms to about 1000 Angstroms from the surface of the semiconductor structure 104. The second cap layer 218 may have a thickness in a range of about 250 Angstroms to about 1000 Angstroms, such as about 500 Angstroms.

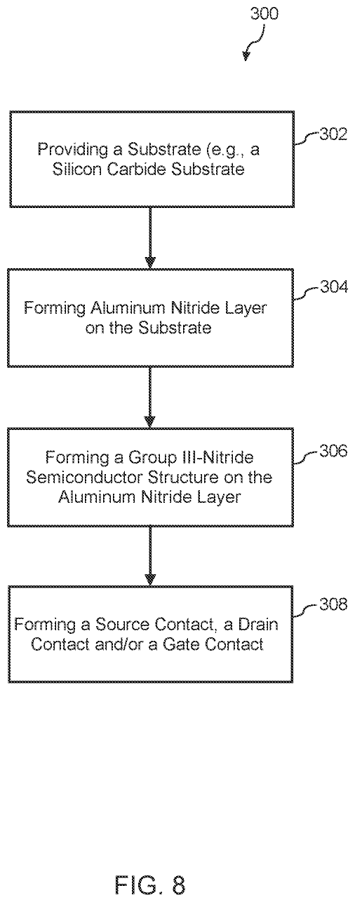

FIG. 8 depicts a flow chart of an example method 300 for fabricating a semiconductor device according to example embodiments of the present disclosure. FIG. 8 depicts example process steps for purposes of illustration and discussion. Those of ordinary skill in the art, using the disclosures provided herein, will understand that the methods described in the present disclosure may be adapted, modified, include steps not illustrated, omitted, and/or rearranged without deviating from the scope of the present disclosure.

At 302, the method 300 may include providing a substrate, such as a silicon carbide substrate. The substrate may be, for instance, the substrate 102 described with reference to FIG. 1.

At 304, the method 300 may include forming an AlN layer on the substrate. The AlN layer may be, for instance, the AlN layer 106 discussed with reference to FIG. 1. The AlN layer 106 may have a thickness in a range of about 200 nm or greater, such as about 300 nm or greater, such as about 500 nm or greater, such as in a range of about 500 nm to about 1000 nm. The AlN layer may be metal-polar (e.g., Al-polar) or N-polar. The AlN layer may be formed on the substrate, for instance, using metal-organic chemical vapor deposition (MOCVD), molecular beam epitaxy (MBE), or hydride vapor phase epitaxy (HVPE).

At 306, the method 300 may include forming a Group III-nitride semiconductor structure on the AlN layer. The Group III-nitride semiconductor structure may include the buffer layer 108 of FIG. 1 or other suitable Group III-nitride semiconductor layers. The Group III-nitride structure, in some examples, may be a multilayer structure. The buffer layer may have a thickness in a range about 700 nm or less, such as about 400 nm or less, such as about 200 nm or less, such as in a range of 100 nm to 700 nm, such as in a range of about 100 nm to about 400 nm. The Group III-nitride semiconductor structure may be metal-polar (e.g., Ga-polar) or N-polar. The Group III-nitride semiconductor structure may be formed on the substrate, for instance, using metal-organic chemical vapor deposition (MOCVD), molecular beam epitaxy (MBE), or hydride vapor phase epitaxy (HVPE).

In some examples, forming a Group III-nitride semiconductor structure on the aluminum nitride layer includes forming a barrier layer on the buffer layer. The barrier layer may have a different band gap relative to the buffer layer. The barrier layer may include AlₓGa₁₋ₓN, where x is 0.1≤ x≤0.4.

At 308, the method 300 may include forming a contact on the semiconductor structure, for instance, to form a semiconductor device. For instance, the method 300 may include forming one or more of a source contact, gate contact, or drain contact to form a transistor device, such as an HEMT device.

Example aspects of the present disclosure are set forth below. Any of the below features or examples may be used in combination with any of the embodiments or features provided in the present disclosure.

One example aspect of the present disclosure is directed to a semiconductor device. The semiconductor device may include a substrate. The semiconductor device may include an aluminum nitride layer on the substrate. The aluminum nitride layer having a thickness of about 200 nm or greater. The semiconductor device may include a Group III-nitride semiconductor structure on the aluminum nitride layer.

In some embodiments, the aluminum nitride layer has a thickness in a range between about 500 nm and about 1000 nm. In some embodiments, a thickness of the aluminum nitride layer is greater than a thickness of the Group III-nitride semiconductor structure. In some embodiments, the aluminum nitride layer has a thermal conductivity that is greater than a thermal conductivity of the Group III-nitride semiconductor structure.

In some embodiments, the aluminum nitride layer and the Group III-nitride semiconductor structure are nitrogen-polar (N-polar). In some embodiments, the aluminum nitride layer and the Group III-nitride semiconductor structure are metal-polar.

In some embodiments, the Group III-nitride semiconductor structure comprises a buffer layer, wherein the buffer layer comprises Al_{w}Ga_{1-w}N, where w is 0≤ w≤0.1. In some embodiments, a thickness of the buffer layer is about 700 nm or less. In some embodiments, the thickness of the buffer layer is about 200 nm or less. In some embodiments, a thickness of the buffer layer is in a range of about 100 nm to about 700 nm.

In some embodiments, the semiconductor device comprises a barrier layer on the buffer layer, wherein the barrier layer comprises AlₓGa₁₋ₓN, where x is 0.1≤ x≤0.4. In some embodiments, the semiconductor device comprises a two-dimensional electron gas (2DEG) at an interface between the buffer layer and the barrier layer.

In some embodiments, the semiconductor device includes one or more cap layers on the Group III-nitride semiconductor structure. In some embodiments, the semiconductor device includes a source contact, a drain contact, and a gate contact on the Group III-nitride semiconductor structure.

In some embodiments, the substrate includes a silicon carbide substrate. In some embodiments, the semiconductor device is a high electron mobility transistor (HEMT) device.

Another example aspect of the present disclosure is directed to a semiconductor device. The semiconductor device may include a substrate. The semiconductor device may include an aluminum nitride layer on the substrate, the aluminum nitride layer having a first thickness. The semiconductor device may include a gallium nitride layer on the aluminum nitride layer; wherein the gallium nitride layer has a second thickness. The first thickness is greater than the second thickness. In some embodiments, the first thickness is at least 1.5 times greater than the second thickness.

In some embodiments, the first thickness is about 200 nm or greater. In some embodiments, the first thickness is in a range between about 500 nm and about 1000 nm.

In some embodiments, the second thickness is about 700 nm or less. In some embodiments, the second thickness is in a range of about 100 nm to about 700 nm.

In some embodiments, the substrate is a silicon carbide substrate. In some embodiments, the semiconductor device is an HEMT device.

Another example aspect of the present disclosure is directed to a transistor device. The transistor device may include a substrate. The transistor device may include a Group III-nitride semiconductor structure on the substrate. The Group III-nitride semiconductor structure may include a first layer on the substrate and a second layer on the first layer. The first layer has a thickness that is greater than a thickness of the second layer. The first layer has a thermal conductivity that is greater than a thermal conductivity of the second layer.

In some embodiments, the N-polar buffer layer comprises N-polar Al_{w}Ga_{1-w}N, where w is 0≤ w≤0.1. In some embodiments, the N-polar buffer layer has a thickness of less than about 700 nm or less. In some embodiments, the N-polar buffer layer has a thickness of about 200 nm or less. In some embodiments, the N-polar buffer layer has a thickness in a range of about 100 nm to about 700 nm.

In some embodiments, the N-polar aluminum nitride layer has a thickness of about 500 nm or greater. In some embodiments, the N-polar aluminum nitride layer has a thickness in a range between about 500 nm and about 1000 nm.

In some embodiments, the transistor device includes one or more cap layers. In some embodiments, the substrate comprises a silicon carbide substrate. In some embodiments, the transistor device is an HEMT device.

Another example aspect of the present disclosure is directed to a method of forming a semiconductor device. The method may include forming an aluminum nitride layer on a substrate. The aluminum nitride layer may have a thickness of about 200 nm or greater. The method may include forming a Group III-nitride semiconductor structure on the aluminum nitride layer.

In some embodiments, the aluminum nitride layer has a thickness in a range of about 500 nm to about 1000 nm. In some embodiments, forming a Group III-nitride semiconductor structure on the aluminum nitride layer comprises forming a buffer layer on the aluminum nitride layer, wherein the buffer layer comprises Al_{w}Ga_{1-w}N, where w is 0≤ w≤0.1. In some embodiments, the buffer layer has a thickness in a range of about 100 nm to about 700 nm.

In some embodiments, forming a Group III-nitride semiconductor structure on the aluminum nitride layer comprises forming a barrier layer on the buffer layer, the barrier layer having a different band gap relative to the buffer layer, wherein the barrier layer comprises AlₓGa₁₋ₓN, where x is 0.1≤ x≤0.4.

In some embodiments, the aluminum nitride layer and the Group III-nitride semiconductor structure are nitrogen-polar (N-polar). In some embodiments, forming a gate contact, a source contact, and a drain contact on the Group III-nitride semiconductor structure.

In some embodiments, the substrate comprises silicon carbide. In some embodiments, the semiconductor device is a high electron mobility transistor (HEMT) device.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A semiconductor device, comprising:
a substrate;
an aluminum nitride layer on the substrate, the aluminum nitride layer having a thickness of about 200 nm or greater; and
a Group III-nitride semiconductor structure on the aluminum nitride layer.

2. The semiconductor device of claim 1, wherein the aluminum nitride layer has a thickness in a range between about 500 nm and about 1000 nm.

3. The semiconductor device of claim 1, wherein a thickness of the aluminum nitride layer is greater than a thickness of the Group III-nitride semiconductor structure.

4. The semiconductor device of claim 1, wherein the aluminum nitride layer has a thermal conductivity that is greater than a thermal conductivity of the Group III-nitride semiconductor structure.

5. The semiconductor device of claim 1, wherein the aluminum nitride layer and the Group III-nitride semiconductor structure are nitrogen-polar (N-polar).

6. The semiconductor device of claim 1, wherein the aluminum nitride layer and the Group III-nitride semiconductor structure are metal-polar.

7. The semiconductor device of claim 1, wherein the Group III-nitride semiconductor structure comprises a buffer layer, wherein the buffer layer comprises AlwGa1-wN, where w is 0≤w≤0.1.

8. The semiconductor device of claim 7, wherein a thickness of the buffer layer is about 700 nm or less.

9. The semiconductor device of claim 7, wherein a thickness of the buffer layer is about 200 nm or less.

10. The semiconductor device of claim 7, wherein a thickness of the buffer layer is in a range of about 100 nm to about 700 nm.

11. The semiconductor device of claim 7, further comprising a barrier layer on the buffer layer, wherein the barrier layer comprises AlxGa1-xN, where x is 0.1≤x≤0.4.

12. The semiconductor device of claim 11, further comprising a two-dimensional electron gas (2DEG) at an interface between the buffer layer and the barrier layer.

13. The semiconductor device of claim 1, further comprising one or more cap layers on the Group III-nitride semiconductor structure.

14. The semiconductor device of claim 1, further comprising a source contact, a drain contact, and a gate contact on the Group III-nitride semiconductor structure.

15. The semiconductor device of claim 1, wherein the substrate comprises a silicon carbide substrate.

16. The semiconductor device of claim 1, wherein the semiconductor device is a high electron mobility transistor (HEMT) device.

17. A semiconductor device, comprising:
a substrate;
an aluminum nitride layer on the substrate, the aluminum nitride layer having a first thickness; and
a gallium nitride layer on the aluminum nitride layer; wherein the gallium nitride layer has a second thickness; and
wherein the first thickness is greater than the second thickness.

18. The semiconductor device of claim 17, wherein the first thickness is at least 1.5 times greater than the second thickness.

19. (canceled)

20. The semiconductor device of claim 17, wherein the first thickness is in a range of about 500 nm and about 1000 nm, and the second thickness is in a range of about 100 nm to about 700 nm.

21-23. (canceled)

24. A transistor device, comprising:
a substrate;
a nitrogen-polar (N-polar) aluminum nitride layer directly on the substrate; and
an N-polar buffer layer directly on the N-polar aluminum nitride layer; and
a two-dimensional electron gas (2DEG) at an interface between the N-polar aluminum nitride layer and the N-polar buffer layer.

25.-55. (canceled)
